(19) United States
(12) Patent Application Publication
(10) Pub. No.: US 2021/0211208 A1
(43) Pub. Date: Jul. 8, 2021

(54) SMART SENSOR SYSTEM AND APPARATUS FOR MEASURING RADIOFREQUENCY AND ELECTROMAGNETIC ENERGY IN REAL TIME

(71) Applicant: Moutie Wali, Coquitlam (CA)

(72) Inventor: Moutie Wali, Coquitlam (CA)

(21) Appl. No.: 17/113,111

(22) Filed: Dec. 7, 2020

Related U.S. Application Data
(60) Provisional application No. 62/945,743, filed on Dec. 9, 2019.

(51) Int. Cl. H04B 17/10; G01R 29/08

(52) U.S. Cl. CPC H04B 17/101; G08C 17/02; G01R 29/0857; G01R 29/0892

(57) ABSTRACT

The present invention relates to an array of smart sensors (system) that measure, in real-time, the combined radiofrequency electromagnetic energy at any given location, identifies the relative contribution of each energy source, and transmits the measured data wirelessly to a central database for performing data analytics. The collected data will be used to determine the degree of regulatory compliance of wireless network operators to various policies on human exposure limits.

Moreover, the invention will enable spectrum management applications, such as determining various cases of interference, identifying spectrum deployment compliance, and assessing the level of out-of-band emissions.

Finally, the data collected can be used to determine areas with excess electromagnetic energy and feed this information to the wireless network to reduce the transmit power of base stations in real-time as part of a Self-Optimized-Network (SON) system. This approach will significantly reduce the power consumption of the base station, enable more efficient energy use, and reduces the carbon footprint.

### FIELD OF THE INVENTION

Technology is changing the way we communicate, the way we share ideas, the way we consume information, and the way we do business. Our society is rapidly evolving into an ultra-connected, ultra-mobile community. Billions of people worldwide own or at least use mobile phones.

This tremendous demand for connectivity has driven mobile network operators around the world to continue densifying their networks by deploying additional infrastructure and increasing offered capacity by adding new frequencies. The potential hazardous effects of excessive use of mobile phones and the increased proliferation of cellular infrastructure continue to steer debate adding pressure on government bodies across the globe for more regulations.

The International Agency for Research on Cancer (IARC) has classified radiofrequency electromagnetic fields as possibly carcinogenic to humans. This has raised additional public concern. Several organizations, like the International Commission on Non-Ionizing Radiation Protection (ICNIRP), the Institute of Electrical and Electronics Engineers, Inc. (IEEE), and the National Council on Radiation Protection and Measurements (NCRP) have issued recommendations for human exposure to RF electromagnetic fields. Many governments around the world have adopted these recommendations, nationally and locally at the municipal level. Different jurisdictions have different regulations in this area.

Mobile network operators, broadcasters, and anyone using wireless transmission to offer services to third parties must limit electromagnetic radiation levels to thresholds specified by law. Service providers typically comply with these laws by using (a) software simulation tools and/or (b) on-site measurements.

(A) Using Software Simulation Tools:

These tools simulate the RF environment and assess the cumulative power density level at various locations around a given desired study area, for example, by generating a heat map of areas exceeding the limits of electromagnetic frequency radiation as recommended by regulatory bodies as shown in the 3D simulation in FIG. 2 (e.g. fields in red are above the required RF threshold).

There are many challenges associated with using these software tools. One is their reliance on accurate records of all RF transmitters in the zone or area under study. Otherwise, the outcome of the simulation lacks accuracy and provides a skewed assessment of the power density levels. Operators may find it challenging to keep up-to-date records of all transmitters on a given cell site because (a) the fast pace of site upgrades makes it challenging to update records continuously, and

(b) many changes do not require physical site intervention (e.g. software upgrades) making them even more difficult to track. Furthermore, since regulatory compliance requires an assessment of combined electromagnetic radiation, for such reports to be accurate, they need to include precise records of all transmitters including those from other operators. Getting accurate technical data about transmitters from competitors adds to these challenges.

Moreover, the power levels of transmitters understudy would vary depending on the amount of traffic carried at any given time, the type of logical configuration used for each cell, or in some cases the distance to the receivers. Hence, the users of these simulation tools would have to rely on assumptions about the total power of transmitters, either using average or maximum values to estimate the input data required to produce the necessary reports.

Finally, since these tools rely on the digital simulation of the RF environment, there is always the inherent risk of inaccuracies between simulated versus actual power density distribution values. The level of precision, in this case, depends on the statistical accuracy of the software algorithm itself. This problem is compounded when estimating the “near field” levels (areas within a few meters from transmitters) where most prediction models tend to perform poorly. The inaccuracy of this method makes it ineffective for adequately assessing compliance.

(B) Using On-Site Measurement:

On-site, field measurement is an accurate method to capture the cumulative electromagnetic power density and assess the level of electromagnetic energy in a given location. However, it is a more expensive method than simulation tools because it requires the use of physical EMF probes. The cost of a single measurement campaign can easily exceed several thousand dollars to complete. This approach would become rapidly impractical given that each operator could have tens of thousands of cell sites. In the US alone there are more than 250,000 sites nationally among all mobile operators.

Another disadvantage of the on-site measurement method is that it provides only a single snapshot in time. Operators continuously upgrade sites, build new infrastructure, making the RF environment rapidly evolving. Therefore, as soon as the measurement campaign is completed it becomes outdated.

Furthermore, it is not always possible to complete field measurement as these campaigns usually require approvals from municipalities or property management facilities to get appropriate access rights.

That is why this method is disadvantageous for evaluating the requirement for a large pool of sites.

Spectrum Ownership Regulations

Furthermore, another important mandate of regulatory bodies around the world is setting the requirements for the ownership, proper use, and operation of a licensed spectrum. Spectrum is a considerable investment and an asset that may appreciate over time. To drive economic development and to avoid the hoarding of the spectrum as a mere investment, regulators monitor the use of spectrum assets closely. Regulators set strict requirements for the proper use of the assets. Such conditions include a predefined schedule for the spectrum deployment, a specific footprint that it needs to cover, or the service of a certain percentage of the population.

The only way regulators can ensure that operators meet these mandatory requirements is by requesting carriers to submit a specific record of operation, or by completing field measurement campaigns. These records submitted by operators are almost always out of date and missing many significant data sets. The upkeep of such information is a significant challenge.

Impact of Future Wireless Technologies

5th generation (5G) mobile networks are the new telecommunications standards.

Small Cell densification, Massive multiple inputs, multiple outputs (MIMO), and Beamforming are some technologies that may serve as the foundation for 5G networks. However, these technologies will have a significant impact on increasing electromagnetic radiation, as discussed below.

(A) Small Cell Densification Technology Wireless networks rely on high powered cell towers to broadcast signals over long distances. However, higher frequencies, such as millimetre wave bands, have difficulty going through obstacles and may cause mobile devices to lose connectivity. Small cell networks would address this problem by using several, (e.g. thousands) of low-powered mini base stations to form a relay team to transmit signals around obstacles. This method is desirable in an environment having several diverse types of obstructions (e.g. an urban environment). Each Small Cell transmits much lower power than a large cell tower and uses smaller antennas making them much smaller in size. This compact size allows Small Cells to be much more versatile, as they could be attached to street furniture. However, each traditional cell tower would need to be replaced by several (e.g. tens if not hundreds of) small cells, especially if a higher frequency is used (such as millimetre wave). The cumulative effect of this method likely causes a great increase in total electromagnetic energy, making this method impractical to comply with regulations, such as those discussed above in FIG. 2.

(B) Massive MIMO Technology

4G base stations supports up to a dozen antenna ports that handle all mobile wireless traffic signals, but massive MIMO base stations can enable the simultaneous transmission over thousands of antenna ports. This feature would allow 5G to support 20 times the capacity offered by 4G and help 5G deliver on its ultra-high-speed capabilities. Although the transmission over a massive number of ports will mean that the transmit power per antenna will be lower than a traditional antenna system, the combined energy of the antenna array would likely significantly increase. The combined energy can reach up to four to ten folds the power of regular 4G sites.

Furthermore, none of the software tools discussed above can simulate an RF environment with Massive MIMO.

5G base stations may consume much higher electrical (utility) power compared to their 4G predecessors. This would cause the carbon footprint of wireless networks to increase.

(C) Beamforming

Beamforming allows the transmit energy to be focused on specific users instead of being broadcast in every direction. As mobile users move, the signal is then reoriented dynamically in time and space towards the direction of the highest demand. Beamforming enables higher efficiency as cell sites can handle more incoming and outgoing data streams at once.

A directional antenna is a passive transmitting element that focuses the electromagnetic energy in a specific direction. The result of the amplification of the signal is called antenna gain. The stronger the concentration of the signal in space, the higher the antenna gain will be. The antenna pattern defines the way the electromagnetic energy propagates in space. The radiation pattern is a unique characteristic of an antenna, and different applications require the use of different types of antennas depending on how concentrated or spread the signal needs to be. FIG. 4 illustrates a directional antenna pattern.

Beamforming allows the antenna pattern to change shape according to the location of traffic. The direction of the maximum gain of the antenna varies depending on where the primary users are. This change is done dynamically in time and space when the location of traffic changes the antenna pattern will adjust automatically. Beamforming may make it more challenging to measure electromagnetic power density using the traditional methods discussed above. Since the antenna pattern is not static in time and space, the simulation tools algorithm may not be able to provide any accurate predictions. Moreover, any on-site measurement needs to be done for an extended period if we want to capture all the dynamic changes in power density levels created by Beamforming technology. Such an approach might increase cost and require more resources making field measurement even more impractical.

There is a need for a solution that measures compliance with existing regulations more effectively.

Any wireless network uses a set of signaling protocols to communicate with the mobile device. One of these protocols is a set of broadcasting messages that allows the very first communication between the network and a new device called Layer 3 messages.

Layer 3 messages are a set of signalling messages that help any mobile device to synchronize and connect to a network. In cellular networks, layer 3 messages ensure the proper communication between the telecommunication network and a device. These messages are generally categorized into three distinct groups: (a) system information messages, (b) dedicated control and information messages, and (c) paging messages.

System information messages are broadcasted to all devices within range and are continuously transmitted at known intervals. This information is received by any capable device as soon as it is switched on and does not require the user equipment to be fully authenticated. The Layer 3 messages help a mobile device synchronize and connect to a network and determine whether or not the device is allowed to connect. It does not authenticate—the authentication process itself comes later.

As an example, LTE network broadcasts system information messages in the form of Master Information Block (MIB) and System Information Block (SIB), once the user equipment is able to synchronize to the network it is able to decode this information. The data collected through MIB and SIB contains critical pieces of information including but not limited to the identification of the operator (called PLMN ID), the identification of the tracking area used to locate the device during an incoming call (called Tracking ID), the identification of the cell (Cell ID), and details about network capabilities (Bandwidth, Power, Modulation, etc.) This information is dynamic, it is updated in real-time. If any change is applied to the network.

It is important to note than Layer 3 messages are not electronic signatures. By contrast an electronic signature is used for identification. Radio-Frequency Identification (RFID) technology is an application of an electronic signature. RFID allows a data encoded in smart tags to be captured by a reader using a wireless communication channel.

For RFID technology, an electronic signal signature is a unique piece of static information (e.g. barcode) specific for each item or device it identifies. It does not change or require any regular updates or modifications over time.

In Layer 3 messages, a real-time view of the network and are continuously updated as soon as the status of the network is changed.

### SUMMARY OF THE INVENTION

The disclosure is directed to a smart sensor system and method for measuring radiofrequency electromagnetic energy. It measures electromagnetic energy in a cellular network in real-time. The data collected is then analyzed and used for a series of applications as described below. The central unit of the smart system is a Smart RF Sensor (SRFS). The SRFS completes the primary scanning, measurement, data collection, and transmitting functions that are then used in the extensive analysis to measure real-time electromagnetic energy.

### BRIEF DESCRIPTION OF THE FIGURES

FIG. 1 shows an embodiment of the system and method in use with a cellular network.

FIG. 2 contains a table that shows exemplary maximum allowable power density figures in an uncontrolled environment in different jurisdictions.

FIG. 3 shows an exemplary 3D simulation of a heat map of areas exceeding electromagnetic frequency radiation limits.

FIG. 4 illustrates an exemplary directional antenna pattern.

FIG. 5 illustrates an exemplary beamforming method.

FIG. 6 illustrates a block diagram for an embodiment of a smart RF sensor system and method.

FIG. 7 illustrates exemplary scanner unit readings in accordance with an embodiment of the system and method of FIG. 6.

FIG. 8 illustrates exemplary baseband unit readings in accordance with an embodiment of the system and method of FIG. 6.

FIG. 9 illustrates exemplary GPS unit readings in accordance with an embodiment of the system and method of FIG. 6.

FIG. 10 illustrates an SRFS data collection and transmission flow chart in accordance with an embodiment of the system and method of FIG. 6.

FIG. 11 contains portions of the charts of FIGS. 7 and 8.

FIG. 12 illustrates a schematic showing an analysis of the source of EMF Radiation.

FIG. 13 shows overview of smart sensor system.

FIG. 14 shows SRFS Capabilities.

### DETAILED DESCRIPTION

The subject matter described relates to an embodiment of a smart sensor system and apparatus for measuring radiofrequency and electromagnetic energy in real-time.

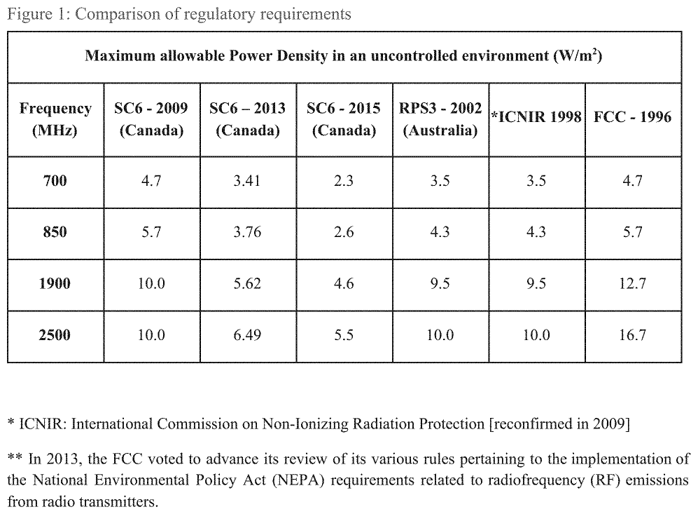

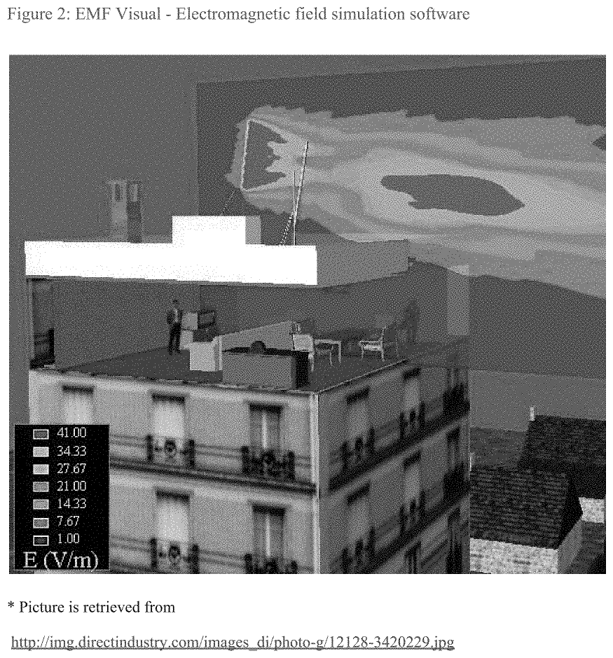

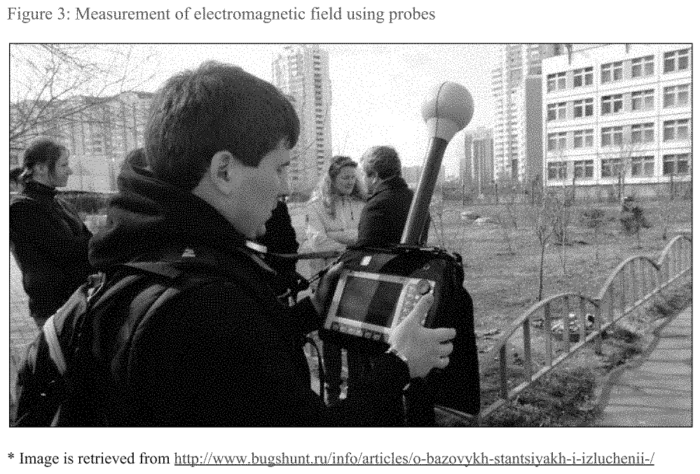

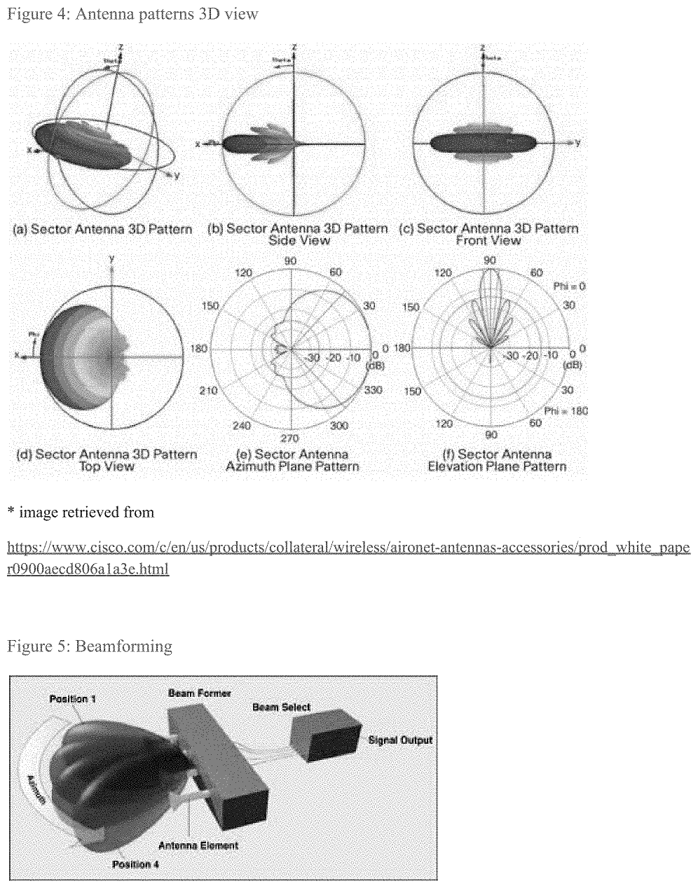

FIG. 1 shows an embodiment of the system and method in use with a cellular network.

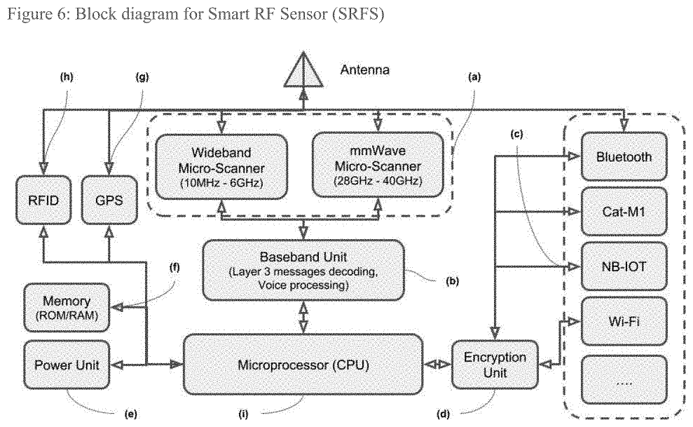

FIG. 6 illustrates a block diagram for a smart RF sensor (SRFS) system and apparatus in accordance with an embodiment and specifically a top-level implementation for the SRFS. In an embodiment, the system has an antenna, a wideband scanner unit, a baseband unit, a communication unit, an encryption unit, a power unit, a GPS unit, an RFID unit, and a microprocessor unit, discussed in detail below.

(a) Antenna & Wideband Scanner Unit

The wideband scanner unit scans and captures the RF electromagnetic waves. It converts electromagnetic waves into electrical signals and passes them to the wideband receiver/scanner to down-convert RF signals into baseband signals. A dual-port or dual antenna system may be used to capture electromagnetic waves in the range of 10 MHz-6 GHz and 28 GHz-40 GHz.

The unit down-converts radio signals into baseband signals. The radio signals contained in the different frequency bands from different carriers are detected and passed onto the baseband module for baseband processing. It simultaneously collects data from these different frequencies across all wireless networks.

(b) Baseband Unit

The baseband unit decodes messages broadcasted by cellular wireless networks to mobile devices.

A wireless network broadcasts network information to all mobile devices within the proximity of a cell site. Because these messages are shared with any mobile device before the authentication by the network, the SRFS will read these messages without being actively connected to the network.

The information shared is called “System Information” or “Layer 3 Messages” and is used by the mobile device to identify among other inputs; the operator of the network, the frequency used by the cell site, the bandwidth of the frequency channel, and Cell ID. For example, in LTE there are two types of system messages; Static and Dynamic information messages. The former is also called Master Information Block (MIB) and is transmitted once every 40 ms, whereas the latter is called System Information Block (SIB) and sent in periodic intervals varying from 80 ms to 320 ms. This information helps the sensor to identify the source of the electromagnetic signal received at any given location. Because the network transmits these messages at regular intervals, any changes to the electromagnetic environment are captured and decoded in real-time.

The baseband unit extracts the different system information blocks from the received signals. The data retrieved by the baseband unit contains the necessary information to identify the specific operator, single base station, the precise cell, and unique frequency as the source of electromagnetic energy.

Moreover, the baseband unit tests the majority of wireless technologies (e.g. determining intermodulation products of two signals residing in neighbouring frequency channels, identifying if a frequency from operator one is encroaching into the frequency channel of a different operator and thus corrupting the signal from operator two). An additional function of the baseband unit is to process a pre-recorded voice message to be used in testing voice emergency services.

(c) Communication Unit The communication unit transmits the data collected by the baseband unit and the wideband scanner to the central database through the wireless network. The implementation of the communication unit could use any wireless technology (e.g. including but not limited to NB-IoT, CAT-ML EDGE, GPRS, GSM, UMTS, CDMA, LTE, WiFi, Bluetooth, Sigfox, etc.).

(d) Data Encryption Unit The data encryption unit protects the data as it moves through the internet by encrypting it. The encryption is done at the sensor level as an extra layer of security before the transmission through the communication unit to the analytics database. Because of the size of the sensors, there is a trade-off between security and what resources are available to implement the encryption (i.e. due to the limited memory size, power consumption, limited bandwidth and execution time for example). In an embodiment, the encryption unit does not have to be a separate unit in the device and could be a function already incorporated in the communication unit, using wireless encryption techniques.

(e) Power Unit The power unit supplies and manages the power requirements for all components inside the sensor system, regardless of where the sensors are located. In an embodiment, the power unit is a battery or cells. All the components inside the sensor are designed for low power consumption and operation to maximize the lifespan of the battery. In a more advanced and sophisticated implementation, electricity may be generated via a magnetic inductive coupling or electromagnetic radiation as these sensors are in the vicinity of these electromagnetic waves.

(g) GPS Unit The GPS unit identifies and tracks the location of the system and all of its components. It provides a location stamp for each transmitted data unit. It uses the GPS satellite system to identify the location of each device.

(h) RFID Unit The RFID unit identifies the SRFS using a mobile device or an RFID reader in order to help determine a sensor for maintenance, inventory, or warehousing purposes.

(i) Microprocessor Unit The microprocessor unit orchestrates the operation and functionality of all system components and allows them to communicate and exchange necessary data or instructions to function correctly. In an embodiment, this unit consumes a relatively small amount of energy in order to help extend battery life.

Overview of the Smart Sensor Network (SSN)

(A) Smart RF Sensor Functionality

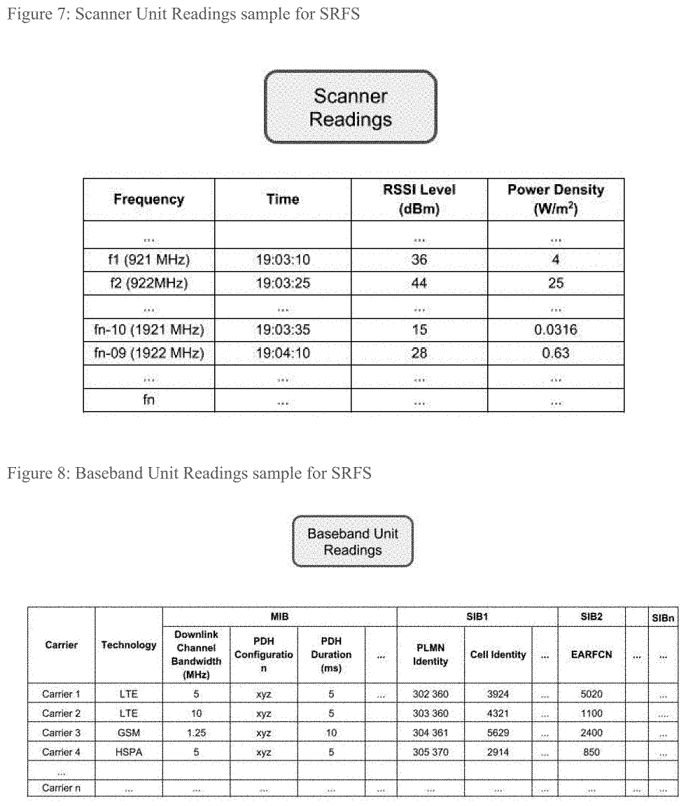

FIG. 7 shows an example of the type of data collected by the wideband scanner. The scanner measures the received signal strength from each frequency and calculates the power density for each discrete channel. In an embodiment, to save power and extend battery life, the frequency scanning function stretches for a predetermined period of time (e.g. 6 minutes as defined in exemplary regulatory requirements, as defined by the user, etc.) and is done based on a predefined cycle time (e.g. once a day or every 8 hours). In an embodiment, the data collected by the scanner is stored locally in the memory unit before being encrypted and then transmitted using the communication unit to the cloud. No post-processing is done locally apart from encryption to reduce processor load and keep the sensor as compact as possible. The readings have a timestamp, which could use the microprocessor clock or an internal clock to help distinguish and identify the data.

FIG. 8 illustrates a sample of the data collected by the baseband unit. The data represents an example of primary Layer 3 messages that are broadcasted by specific cellular networks (e.g. including GSM, HSPA, and LTE). The baseband unit is able to decode these messages and store them in the local memory unit before being encrypted and then transmitted to the cloud for further analysis. The system broadcast messages are sent at regular short intervals. As an example, the LTE networks transmit system messages for a cycle time that varies from 40 ms to 320 ms. Since it is unlikely the wireless RF environment will change within these intervals and in order to save processing power and to save battery life, the baseband unit scans for broadcast messages and decodes them on much longer cycles. The end-user is able to define these cycle times. The shorter the cycle time, the shorter the lifetime of the battery. The time of measurement should also coincide with the time interval used by the RF Scanner to measure received power density as discussed in the previous paragraph. This requirement is essential to help link the data collected by the wideband scanner to that obtained by the baseband unit.

Other factors will be used to correlate the two sets of data, discussed in more detail below.

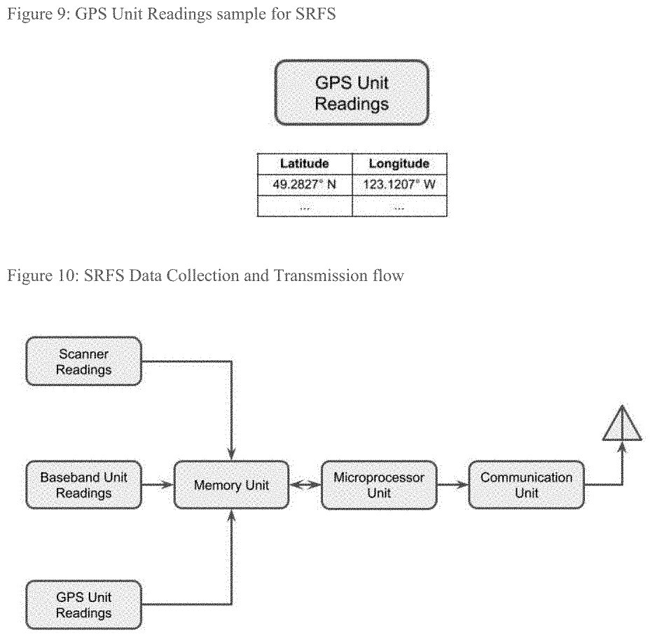

FIG. 9 provides a view of the readings from the GPS Unit that will be used to provide an accurate location of the SRFS. Since the sensor is expected to be stationary the readings from the GPS Unit could be done on a much longer cycle than the reading/measurements done by the wideband scanner or the baseband unit as discussed in the previous two paragraphs.

FIG. 10 shows the flow of data from the different units discussed above to the local memory before being encrypted and then transmitted to the cloud to reach the central database for further analysis. In an embodiment, the post-processing and manipulation of the raw data are done in the cloud to reduce the requirement for local memory resources, processing power, and battery usage at the SRFS.

(B) System Data Analysis

The system analyzes the data after it collects it. The system provides a very accurate assessment of the source of electromagnetic energy for each transmitted frequency by correlating the data collected from the wideband scanner and the baseband unit. The Layer 3 messages obtained by the baseband unit contains key network information including the EARFCN number which represents the center frequency used by the serving cell site. This frequency is the common denominator that links the data from the baseband unit to the data collected by the wideband scanner. The system relates every frequency measured from the wideband scanner with its corresponding value in the data decoded by the baseband unit. At the completion of this step, the device associates the power density data with the corresponding identification data.

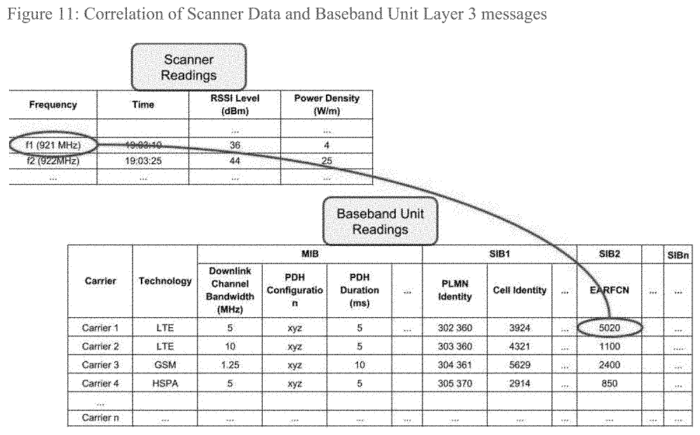

The outcome is a list of frequencies, with a measured electromagnetic power level, the specific source including the operator (PLMN ID), the transmitting cell (Cell ID), the source base station (eNodeB ID), the type of modulation used, etc. FIG. 11 shows a summary of the procedure.

Not every frequency measured by the wideband scanner has a corresponding EARFCN value in Layer 3 messages decoded by the baseband unit. As an example, wireless networks using an unlicensed spectrum (WiFi for example) do not rely on broadcasting channels as in the case of cellular networks. For these specific frequencies, the device relies on traditional methods to identify the source of radiation including regulatory spectrum database or other data sources.

In an embodiment, the system tests emergency voice services using a pre-recorded message in the baseband unit that is transmitted using the communication unit to a central server. The system verifies automatically, without any manual intervention, if the voice message has been successfully received and decoded through the network.

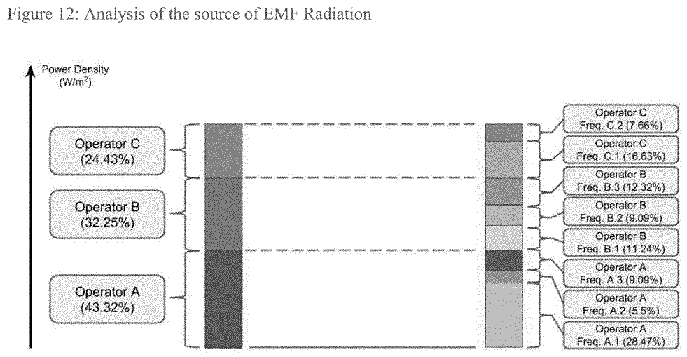

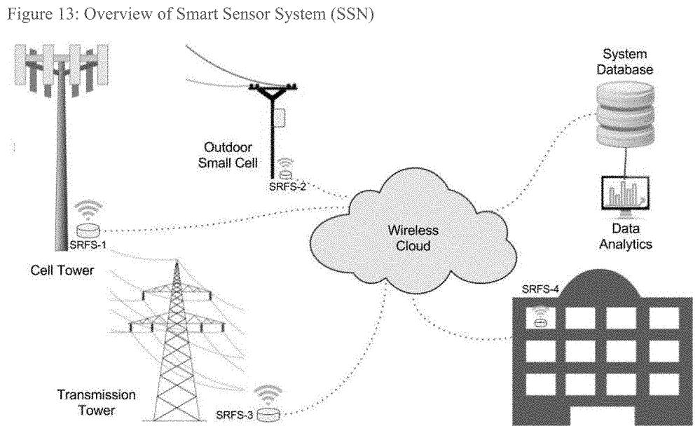

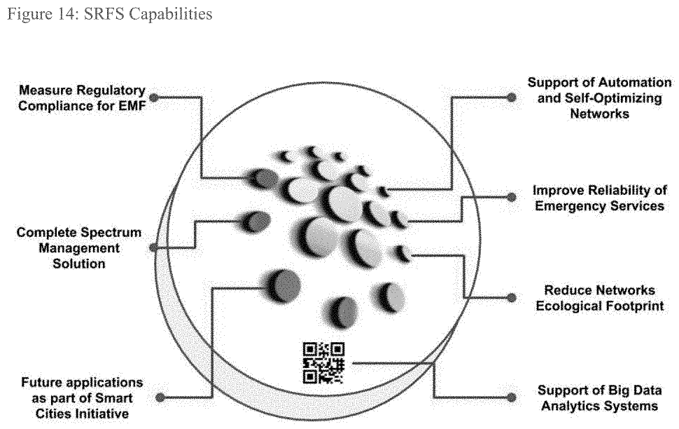

(1) Use of Layer 3 messages for identification of electromagnetic sources: The system uses the information in Layer 3 messages to identify the source of electromagnetic radiation and their relative contribution to overall electromagnetic energy at any given point comprising.
(a) A Smart Sensors Network of measuring electromagnetic energy in real-time:
The Smart Sensor Network system uses the Internet of Things technology to allow real-time continuous measurement of electromagnetic energy radiation. The information is collected and shared in real-time with a server to allow for trend analysis and system monitoring, for example, to help regulators to maintain radiofrequency radiation at safe levels for the public.
The SSN provides real-time measurement of RF radiation, providing a view of how RF energy is changing over time. Such a dynamic view allows for continuous monitoring of the exposure levels even when the RF ecosystems change through network upgrades or new infrastructure build-out. This feature allows regulators and operators to avoid repeat measurement campaigns or iterative simulations using the software every time a new change in the network is perceived.
Moreover, the SSN allows for accurate identification of the source of each frequency by determining accurately, which frequency channel, and which operator contributes most of the overall power density. This feature facilitates taking corrective measures as the party who has the highest contribution to the total power density level will have to reduce the transmit power or make necessary changes to the network configuration to avoid overexposure. FIG. 12 shows an example of such analysis for multiple operators, where it illustrates the possibility of identifying not only the relative contribution of each network carrier but also the exact contribution of each frequency channel. With these details, network operators can determine with high precision the specific frequency carrier for which the transmit power will need to be adjusted.
(b) An apparatus that measures electromagnetic energy in real-time, comprising:
An antenna and Wideband Scanner Unit (see sections [017] & [018] for details);
A baseband unit (see sections [019], [020], [021] & [022] for details);
A communication unit (see section [023] for details);
An encryption unit (see section [024] for details);
A power unit (see section [025] for details);
A GPS unit (see section [026] for details);
An RFID unit (see section [027] for details);
A microprocessor unit(see section [028] for details).
(c) A new methodology for spectrum management
As discussed in the background section regulatory have significant challenges maintaining a database of spectrum use and deployment. Since the SSN uses Smart Sensors that have a Wideband Scanner, and include a GPS antenna, as well as provide real-time data, it is then possible to identify precisely when and where a new frequency channel has been activated. If the operator uses a protocol that includes broadcast channels it is then possible to determine the specific operator that has used the spectrum. These tasks are all done in real-time and without any field intervention or manual record keeping.
Another primary concern of regulatory is to ensure that the licensed spectrum is free of external interference (or at least kept at marginal levels). One of the ways this is accomplished is by setting explicit rules for Out-Of-Band and spurious emissions limits (OOB). OOB refers to the amount of power transmitted immediately outside the assigned bandwidth which results from the modulation process. Spectrum licensees are expected to use special filters to reduce the number of OOB emissions. If these filters become faulty or are not compliant with the OOB emissions standards, they can cause severe interference to adjacent frequency bands used by other licensees. Since our invention can measure the power received from every frequency and can identify the specific bandwidth used by each licensee from Layer 3 messages (Baseband Unit), it is theoretically possible for our SSN to determine the levels of OOB and report these figures as part of the data analytics set. This information can then be used by regulators or licensees to identify instances of serious OOB for preventive maintenance or conflict resolution when two or more licensees experience serious interference issues. The FCC documented an unusual case of interference between the Wireless Communications Service (WCS) band (2305-2320 and 2345-2360 MHz), used in the cellular network, and the Satellite Digital Audio Radio Service (SDARS), used for SiriusXM satellite radio, in the US. FCC concluded after several years of analysis that more stringent OOB is required [12]. This issue could have been identified and easily rectified using the SSN in matters of days if not hours.
(d) A new methodology for utility grids preventive maintenance In an embodiment, the system and method may be used to collect data from the distribution grids and identify the variability in the signal and correlate such data with the performance of the network. Machine learning algorithms can be used in causation analysis to forecast future outages. Such a feature could be then used to predict when and where preventive maintenance procedures need to be completed.
(e) A new methodology to reduce power consumption for wireless networks
In an embodiment, the system and method may be used to measure the received power from cell sites across a network and help identify areas where there is an excess level of the signal, with the support of a Self-Optimizing Network the system will ensure proper regulation of such transmissions. This will in turn help reduce wasted energy and improve the overall energy consumption. By regulating the power transmitted it will be possible to improve the overall efficiency of the network and decrease the ecological footprint.
